(19) United States
(12) Patent Application Publication
(10) Pub. No.: US 2013/0056799 A1
(43) Pub. Date: Mar. 7, 2013

(54) CIRCUIT SIMULATION METHOD AND SEMICONDUCTOR INTEGRATED CIRCUIT

(71) Applicant: PANASONIC CORPORATION, Osaka (JP)

(72) Inventor: Tomoyuki ISHIZU, Kyoto (JP)

(73) Assignee: PANASONIC CORPORATION, Osaka (JP)

(21) Appl. No.: 13/667,749

(22) Filed: Nov. 2, 2012

Related U.S. Application Data
(63) Continuation of application No. PCT/JP2011/001046, filed on Feb. 24, 2011.

(30) Foreign Application Priority Data
May 13, 2010 (JP) 2010-111390

(51) Int. Cl. G06F 17/50; H01L 27/04

(52) U.S. Cl. 257/213; 716/136; 257/E27.01

(57) ABSTRACT

A simulation method of a circuit in which a transistor is formed of a material (e.g., SiGe, etc.) having a lattice constant different from that of a semiconductor substrate, on source and drain regions, an adjacent active region is formed near the transistor, and a gate electrode is formed in the active region, where a region not overlapping with the gate electrode in the adjacent active region is formed of a material such as SiGe, includes a step of calculating an electrical characteristic (e.g., flowing current, threshold voltage, etc.) of the transistor based on a distance between an edge closer to the transistor, of both edges of the adjacent active region disposed near the transistor, and the gate electrode formed in the adjacent active region. Thus, circuit simulation can be performed with high accuracy with respect to an electrical characteristic of the transistor.

### CROSS-REFERENCE TO RELATED APPLICATION

This is a continuation of PCT International Application PCT/JP2011/001046 filed on Feb. 24, 2011, which claims priority to Japanese Patent Application No. 2010-111390 filed on May 13, 2010. The disclosures of these applications including the specifications, the drawings, and the claims are hereby incorporated by reference in their entirety.

### BACKGROUND

The present disclosure relates to a circuit simulation method and semiconductor integrated circuits (ICs) designed using the circuit simulation method, and more particularly to a method for providing a circuit simulation with high accuracy taking into consideration the effects of strain due to mechanical stress on electrical characteristics of a transistor, and semiconductor ICs designed using such a circuit simulation method.

In recent years, there has been a need for further improving the accuracy of simulation by circuit simulators during development of system large scale integrated circuits (LSIs) etc. Specifically, as the feature sizes in semiconductor processes decrease, the layout pattern and/or arrangement of circuit elements tend to have a significant effect on the performance of semiconductor ICs. In particular, a transistor using an element isolation technique such as shallow trench isolation (STI) exhibits a phenomenon in which strain, due to mechanical stress applied from an element isolation region to the transistor, changes the mobility in a channel region, thereby causing a significant change in electrical characteristics of the transistor. Such a phenomenon draws attention as a factor that hinders improvement of the accuracy of circuit simulation.

As the feature sizes decrease, it is becoming increasingly difficult to provide a greater driving force by a conventional scaling, and accordingly technology which actively utilizes an increase in mobility due to strain is being developed. For example, a method has been proposed in which SiGe is introduced in the source and drain regions in a p-channel metal oxide semiconductor (PMOS) transistor formed on a Si substrate. Since the lattice constant of SiGe is greater than that of silicon, a larger compressive strain is induced in the channel region between the source and drain regions formed of SiGe. Use of such a technique can increase hole mobility.

However, introduction of such a technique may cause a significant change in electrical characteristics of a transistor depending on the layout pattern and/or arrangement of SiGe regions. In particular, since differential amplifier circuits, current mirror circuits, etc. use a large number of transistor pairs which are required to have only relatively small characteristic differences, a change in characteristics due to the layout pattern may have an effect on circuit performance, on the yield rate, etc. Therefore, the change in characteristics due to the layout pattern needs to be estimated with high accuracy during the design stage.

In order to provide circuit simulation taking into consideration a change in strain caused by mechanical stress due to the layout pattern, conventional techniques define the geometry of an active region disposed near the transistor, such as the width of the element isolation region, the length of an active region adjacent to the transistor across the active region, etc., as the indices of the strain applied to the transistor, and propose high-accuracy circuit simulation methods with respect to electrical characteristics using a mathematical model using such geometric parameters. One of such proposed methods is described, for example, in Japanese Patent Publication No. 2008-085030.

### SUMMARY

FIG. 1 illustrates a plan view and a cross-sectional view of a simulated circuit for explaining geometric parameters used in a mathematical model which describes electrical characteristics of a transistor in a conventional circuit simulation method. The cross-sectional view is taken along line A-A″ of the plan view.

In FIG. 1, an active region 2 (a region indicated by bold lines in FIG. 1) surrounded by an element isolation region 1 is formed on a semiconductor substrate S, and the active region 2 and a gate electrode 3 together form a transistor 4. Here, the channel length direction is defined as a direction parallel to the direction in which a source-to-drain current of the transistor 4 flows, and the channel width direction is defined as a direction perpendicular to the current direction. The length, along the channel length direction, of the gate electrode 3 included in the transistor 4 is defined as a gate length L, and the width, along the channel width direction, of a region where the gate electrode 3 and the active region 2 overlap is defined as a channel width W of the transistor 4.

A channel region 5 of the transistor 4 is strained due to the difference between the coefficients of thermal expansion of the element isolation region 1 and of the active region 2, etc., thereby causing a change in electrical characteristics. The strain in the channel region 5 is affected not only by the layout pattern of the active region 2 and of the element isolation region 1, but also by the layout pattern of an active region 6 (a region indicated by other bold lines in FIG. 1) disposed across the element isolation region 1 along the channel length direction. The convention technique defines the distance 7 from one edge to the other edge of the active region 6 as a parameter relating to the characteristic change due to the layout pattern of the active region 6 disposed nearby, and uses that parameter in an approximation formula which represents electrical characteristics.

However, when a transistor is configured such that a material (e.g., SiGe) different from that of the semiconductor substrate (e.g. Si substrate) is introduced in the source and drain regions 8 for improvement in mobility, and thus compressive strain is induced in the channel region 5, formation of a SiGe-introduced region results in a configuration in which the region underneath a gate electrode 9 is the Si substrate, and a SiGe region is formed in the active region other than the gate electrode 9 if the gate electrode 9 is formed on the active region 6 disposed near the transistor 4. This process creates two regions respectively formed of different materials in the active region 6 disposed near the transistor 4. In addition, as the ratio of the SiGe region in the active region increases, the magnitude of the compressive strain induced increases for a same active region area.

Based on these facts, the conventional technique, which only defines the width of the active region disposed near the transistor as a parameter, and takes the parameter into consideration, may fail to provide sufficient accuracy of circuit simulation, and may therefore lead to a circuit performance degradation and a reduction in the yield rate.

It is an object of the present disclosure to solve the foregoing problems of the conventional technique, and to provide a circuit simulation method having a relatively small simulation error, and a semiconductor IC, for which a change in electrical characteristics due to the layout pattern is estimated during the design stage, thereby avoiding a circuit performance degradation and a reduction in the yield rate.

In order to solve these problems, a circuit simulation method of the present disclosure provides a circuit simulation for electrical characteristics of a transistor based on the shape and size of a region not overlapping with the gate electrode in the active region near the transistor, if the active region near the transistor includes two regions respectively formed of different materials as described above (e.g., the region underneath the gate electrode 9 is the Si substrate, and the active region other than the gate electrode is a SiGe region).

Specifically, the present disclosure provides a circuit simulation method for calculating, using a computer and a memory, an electrical characteristic of a transistor formed on a semiconductor substrate and having an active region and a gate electrode surrounded by an element isolation region, in a circuit including the transistor, the circuit also including both an adjacent active region disposed across the element isolation region in a gate length direction of the transistor, and an adjacent gate electrode disposed on the adjacent active region in parallel to the gate electrode of the transistor, where a region not overlapping with the adjacent gate electrode in the adjacent active region is formed of a material having a lattice constant different from that of the semiconductor substrate, which includes storing by the computer in the memory a gate length and a channel width of the transistor, and a distance between an edge closer to the transistor, of both edges of the adjacent active region, and the adjacent gate electrode as a first geometric parameter, and calculating by the computer the electrical characteristic of the transistor based on the gate length and the channel width of the transistor and on the first geometric parameter stored in the memory.

Thus, when a circuit simulation method of the present disclosure is used for a circuit simulation of electrical characteristics of a transistor in which the source and drain regions are formed of a material (e.g., SiGe, SiC, etc.) different from that of the semiconductor substrate, where the region underneath the gate electrode formed on the adjacent active region disposed near the transistor is formed of the material of the semiconductor substrate such as Si, and at the same time the region other than the gate electrode in the adjacent active region is formed of a material (e.g., SiGe, SiC, etc.) different from that of the semiconductor substrate, the circuit simulation method provides the circuit simulation of electrical characteristics based on a distance between the edge closer to the transistor and the adjacent gate electrode on the adjacent active region with respect to the geometry of the adjacent active region. This method enables a circuit simulation to be performed with high accuracy taking into consideration the effect of the adjacent active region near the transistor, thereby improving the accuracy of the simulation.

As described above, even if the region underneath the gate electrode formed on the adjacent active region disposed near the transistor is formed of a material of the semiconductor substrate, and at the same time the region other than the gate electrode in the adjacent active region is formed of a material (e.g., SiGe, SiC, etc.) different from that of the semiconductor substrate, a circuit simulation method of the present disclosure enables a circuit simulation to be performed taking into consideration the effect of the adjacent active region near the transistor, thereby improving the accuracy of the simulation.

### BRIEF DESCRIPTION OF THE DRAWINGS

FIG. 1 illustrates a plan view and a cross-sectional view of a simulated circuit for explaining geometric parameters used in a conventional circuit simulation method.

FIG. 2 illustrates a plan view and a cross-sectional view of a simulated circuit for explaining geometric parameters used in the circuit simulation method according to the first embodiment of the present disclosure.

FIG. 3 is a diagram comparing a result of a process simulation of the dependence of the drain current of a transistor on the layout of the adjacent active region, with a result of a simulation performed using a modeling technique according to the present invention.

FIG. 4 is a flowchart illustrating a technique for reflecting, in circuit design, the circuit simulation method according to the first embodiment of the present disclosure.

FIG. 5 illustrates a plan view and a cross-sectional view of a simulated circuit for explaining geometric parameters used in the circuit simulation method according to the second embodiment of the present disclosure.

FIG. 6 illustrates a plan view and a cross-sectional view of a simulated circuit for explaining geometric parameters used in the circuit simulation method according to the third embodiment of the present disclosure.

FIG. 7 illustrates a plan view and a cross-sectional view of a simulated circuit for explaining geometric parameters used in the circuit simulation method according to the fourth embodiment of the present disclosure.

FIG. 8 illustrates a plan view and a cross-sectional view of a simulated circuit for explaining geometric parameters used in the circuit simulation method according to the fifth embodiment of the present disclosure.

FIG. 9 illustrates a plan view of a simulated circuit for explaining geometric parameters used in the circuit simulation method according to the sixth embodiment of the present disclosure.

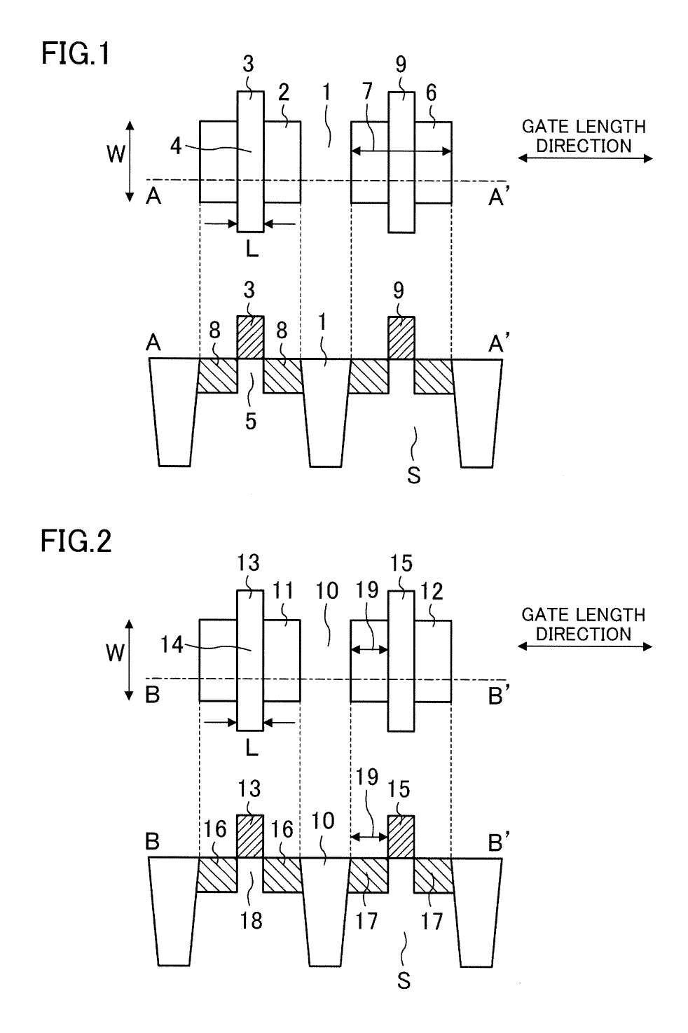

### DETAILED DESCRIPTION

### First Embodiment

The first embodiment of the present disclosure will be described below with reference to the drawings. FIG. 2 illustrates a plan view and a cross-sectional view of the layout pattern of a transistor which is simulated using the circuit simulation method according to this embodiment. The cross-sectional view is taken along line B-B′ of the plan view.

In FIG. 2, a first active region 11 (a region indicated by bold lines in FIG. 2) and a second active region (adjacent active region) 12 (a region indicated by other bold lines in FIG. 2) disposed near the first active region 11 are formed and disposed spaced apart from each other on a semiconductor substrate S. The first active region 11 and the second active region 12 are separated from each other by an element isolation region 10, which is formed by an insulation film. A gate electrode 13 is formed in the first active region 11, forming a transistor 14.

Here, the channel length direction is defined as a direction parallel to the direction in which a source-to-drain current of the transistor 14 flows, and the channel width direction is defined as a direction perpendicular to the current direction. The length, along the channel length direction, of the gate electrode 13 included in the transistor 14 is defined as the gate length L, and the width, along the channel width direction, of a region where the gate electrode 13 and the active region 11 overlap is defined as the channel width W of the transistor 14. A gate electrode (adjacent gate electrode) 15 is formed in the second active region 12 in parallel to the gate electrode 13.

In each of active regions which do not overlap with the gate electrode 13 in the active region 11 or with the gate electrode 15 in the active region 12, a material different from that of the semiconductor substrate (e.g., Si substrate) S is introduced in a region at a depth of approximately 100 nm to 100 μM below the surface. A different material means a material having a lattice constant different from that of Si, such as SiGe, SiC, etc.

High-strain regions 16, in which a material different from that of the semiconductor substrate S is introduced, are formed in the active region 11 of the transistor 14; and high-strain regions 17 are formed in the second active region 12. The high-strain regions 16 formed in the active region 11 and the high-strain regions 17 formed in the active region 12 may be formed of different materials. For example, these high-strain regions may be configured such that the high-strain regions 16 have SiGe introduced, and the high-strain regions 17 have SiC introduced.

If the high-strain regions 16 are formed of SiGe, then the lattice constant is greater than that of Si, thereby causing a compressive strain in a channel region 18 formed underneath the gate electrode 13. In contrast, if the high-strain regions 16 are formed of SiC, then the lattice constant is less than that of Si, thereby causing a tensile strain in the channel region 18. In addition, the high-strain regions 17 formed in the active region 12 disposed near the transistor 14 across the element isolation region 10 also have an effect of inducing a strain in the channel region 18, which is not negligible.

A strain induced in the channel region 18 depends on the sizes of the high-strain regions 17 formed in the active region 12. A larger distance (first geometric parameter) 19 along the channel length direction between the edge closer to the transistor 14, of both the edges of the second active region 12 in the channel length direction, and the opposing edge of the gate electrode 15 induces a larger strain in the channel region 18. Thus, a change in an electrical characteristic of the transistor 14 can be represented by a function of the distance 19. Specifically, in order to describe an electrical characteristic change ΔP due to the geometry of an active region near the transistor, let a geometric parameter A denote, as a model parameter, the distance 19 between the edge of the active region 12 near the transistor 14 and the gate electrode 15, then the electrical characteristic change ΔP can be defined by Equation 1-a as follows.

ΔΔP∝f(A,W,L) (1-a)

In this embodiment, Equation 1-b may be used instead of Equation 1-a.

ΔP∝f₁(A^{α})×f₂(W,L) (1-b)

where α is a fitting parameter modeling the change in an electrical characteristic with a change in the geometric parameter A; and f(W, L) is a term representing dependence on the channel width W and the gate length L of the transistor. Dependence on the channel width is taken into consideration here because electrical characteristics are affected by mechanical stress applied from an adjacent active region disposed along the channel width direction, and thus the electrical characteristic change with the geometric parameter A may change depending on the channel width. Moreover, since the susceptibility of mobility to the transistor current depends on the value of the gate length, and since there exists a strong correlation between the mobility and the magnitude of strain, dependence on the gate length needs to be taken into consideration.

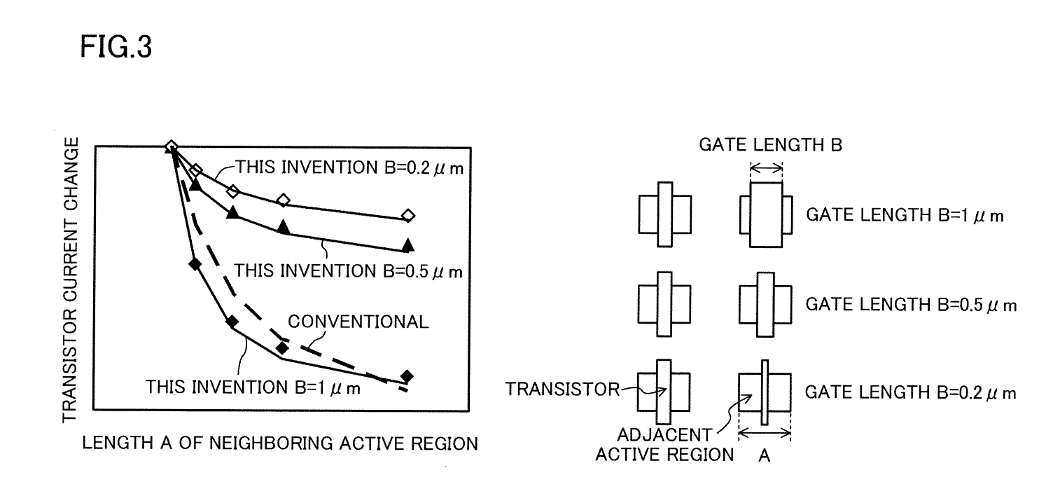

FIG. 3 illustrates a comparison of a result of calculation by a process simulation of a change in the drain current with respect to a layout of an active region disposed near the transistor with results of a circuit simulation according to this embodiment with respect to a PMOS transistor in which SiGe is introduced in the source and drain regions.

In FIG. 3, the horizontal axis represents the length A, along the channel length direction, of an active region disposed near the transistor (adjacent active region), and the vertical axis represents the change of the transistor current. The points represent the results calculated by a process simulation which calculates the strain due to SiGe introduced in the source and drain regions, and then calculates the change of the current due to the strain. Here, the black diamond symbols each indicate a result for the length (gate length) B of 1 μm of the gate electrode along the channel length direction on an adjacent active region; the triangle symbols each indicate a result for the gate length B of 0.5 μm; and the white diamond symbols each indicate a result for the gate length B of 0.2 μm. The solid lines represent the results of a circuit simulation according to this embodiment, and the dashed line represents the result of a conventional circuit simulation.

The results of the process simulation show that, even if the length A of the adjacent active region is the same, different values of the gate length B of the adjacent gate electrode induce significantly different changes in the transistor current. A greater value of the gate length B of the gate electrode results in a larger current change. The reason is that, if the length A of the adjacent active region is small, then a greater gate length B results in a smaller ratio of the area occupied by the active region into which SiGe is introduced, thereby reducing the strain having an effect on the channel region of the transistor. Accordingly, a larger length A of the active region causes the region into which SiGe is introduced to become larger, thereby eventually causing the amount of change in the strain to be increased.

A small gate length B of the gate electrode results in a relatively large ratio of the SiGe region even if the length A of the active region is small, thereby causing the amount of change in the strain to be small with respect to the length A of the active region. In this regard, the conventional technique does not take into consideration the ratio of the SiGe region to the length A of the active region, and thus a result of a circuit simulation exhibits no change with respect to a change in the gate length B, which creates a large error.

In contrast, the circuit simulation method according to this embodiment defines the length, along the channel length direction, of the SiGe region with respect to the length A of the active region as a geometric parameter, and calculates electrical characteristics of the transistor taking into consideration both the structure of the transistor and the mechanism of inducing strain. Thus, a circuit simulation can be performed with higher accuracy with respect to the geometry of an active region near the transistor.

Examples of electrical characteristics affected by the geometry of an active region near the transistor include transistor current, threshold voltage, and leakage current. This is because a change in strain in the channel region of the transistor causes the mobility to change, thereby causing the transistor current to change. In addition, a change in the impurity distribution due to strain during a transistor manufacturing process causes threshold voltage and/or junction leakage current to change.

Although FIG. 2 illustrates the active region disposed near the transistor 14 only on one side along the channel length direction, active regions may be formed on both the left and right sides of the transistor 14 to respectively form an adjacent active region and an opposite adjacent active region, and an adjacent gate electrode and an opposite adjacent gate electrode may respectively be formed in these adjacent active regions. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of both the left and right sides achieves a high-accuracy circuit simulation even if the active regions disposed on the both sides of the transistor 14 along the channel length direction have geometries different from each other.

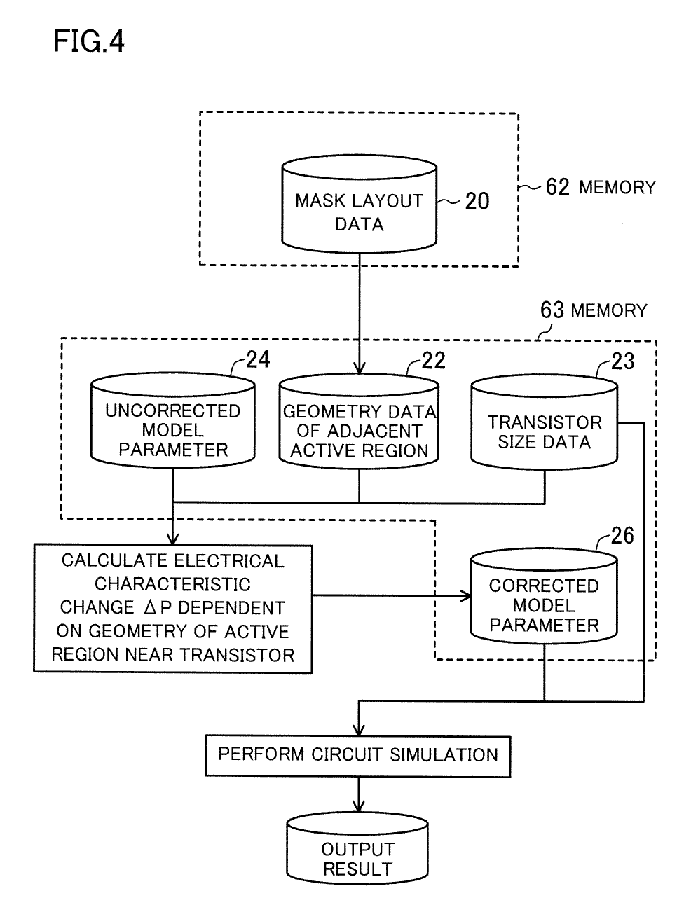

Next, a technique for reflecting, in circuit design, a change in electrical characteristics affected by the geometry of an active region near the transistor will be described below using FIG. 4.

In FIG. 4, the circuit simulation device according to this embodiment includes a computer (not shown) and a memory 63. The computer first extracts geometry data 22 of the active region disposed near the transistor from mask layout data 20 having design information of the simulated circuit, and stores the geometry data 22 in the memory 63. The geometry data 22 of the active region disposed near the transistor includes the distance (first geometric parameter) 19 along the channel length direction between the edge closer to the transistor 14, of both the edges of the adjacent active region 12, and the gate electrode 15 as illustrated in FIG. 2.

The computer also stores transistor size data 23, including the gate length L, the gate width W, etc. of the transistor 14 obtained from the design information of the simulated circuit, and transistor model parameters (uncorrected model parameters) 24 which determine electrical characteristics of the transistor 14, in the memory 63. The transistor model parameters 24 are extracted from data of the electrical characteristics of the transistor when the geometry of the active region disposed near the transistor 14 is fixed to a predetermined pattern; that is, the transistor model parameters 24 are those before geometry dependence is taken into consideration.

Then, the computer calculates the electrical characteristic change ΔP due to the geometry of the active region near the transistor 14 based on Equation 1-a or Equation 1-b using the geometry data 22 of the adjacent active region and the transistor size data 23 stored in the memory 63. Here, the electric parameters of the transistor 14 calculated as the electrical characteristic change ΔP include transistor current, threshold voltage, junction leakage current, etc.

Since calculation of the electrical characteristic change ΔP enables the electrical characteristics to be taken into consideration based on the geometry of the active region disposed near the target transistor 14, a high-accuracy circuit design can be achieved.

For example, an effect can be examined at a circuit level by taking into consideration the electrical characteristic change ΔP in circuit simulation using a MOSFET model such as BSIM3 or BSIM4 developed at the University of California, Berkeley.

Specifically, if, in MOSFET models such as BSIM3 and BSIM4, the transistor model parameters 24 is arranged so as to include model parameters which determine a transistor current, a threshold voltage, and a junction leakage current that provide the electrical characteristics of a transistor, the transistor current Id is expressed by Equation 2 shown below including a carrier mobility parameter U0, a source/drain parasitic resistance parameter RDSW, and a saturation velocity parameter VSAT in the MOSFET models.

Id=F(U0,RDSW,VSAT) (2)

The threshold voltage Vth is expressed using a threshold voltage parameter VTH0 when the gate-to-drain voltage is zero, and the gate length is large. The threshold voltage Vth is expressed by Equation 3 as follows.

Vth=G(VTH0) (3)

The junction leakage current Ij is expressed using parameters JTSSWGS and JTSSWGD, which respectively represent current intensities of currents flowing through the PN junction underneath the gate on the source and drain sides. The junction leakage current Ij is expressed by Equation 4 as follows.

Ij=H(JTSSWGS,JTSSWGD) (4)

Thereafter, the transistor model parameters 24 including the transistor current Id, the threshold voltage Vth, and the junction leakage current Ij described above are corrected depending on the geometry of the active region disposed near the target transistor, based on a transistor current change ΔP_Id, a threshold voltage change ΔP_Vth, and a junction leakage current change ΔP_Ij calculated as the electrical characteristic change ΔP. Specifically, letting U0′, RDSW′, VSAT′, VTH0′, JTSSWGS′, and JTSSWGD′ denote the respective corrected parameters, the parameters are corrected as Equation 5 shown below.

U0′=U0×ΔP_{—}Id

RDSW′=RDSW/ΔP_{—}Id

VSAT′=VSAT×ΔP_{—}Id

VTH0′=VTH0+ΔP_{—}Vth

JTSSWGD′=JTSSWGD×ΔP_{—}Ij

JTSSWGS′=JTSSWGS×ΔP_{—}Ij (5)

The corrected model parameters 26 are thus generated. A circuit simulation by the computer using the corrected model parameters 26 and the transistor size data 23 stored in the memory 63 can reflect the electrical characteristic change dependent on the geometry of each of the active regions disposed near each of the transistors in a circuit. Accordingly, semiconductor ICs can be fabricated while avoiding a circuit performance degradation and a reduction in the yield rate.

### Second Embodiment

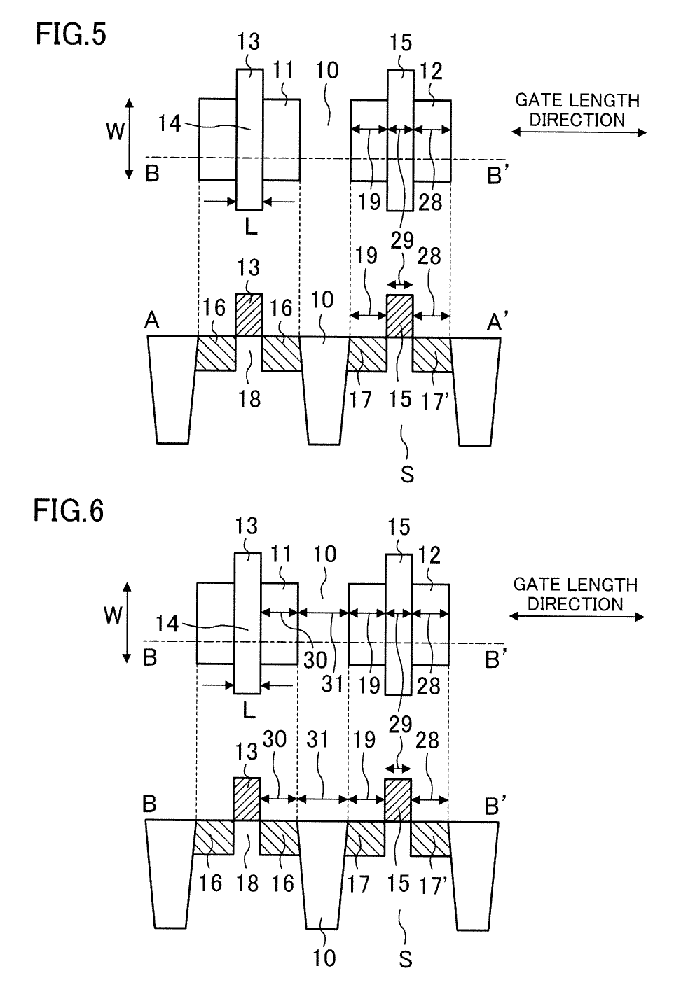

FIG. 5 illustrates a plan view and a cross-sectional view of a circuit simulated using the circuit simulation method according to the second embodiment of the present disclosure. The cross-sectional view is taken along line B-B′ of the plan view. The same or equivalent structures to those of the first embodiment are designated by the same reference characters.

In FIG. 5, similarly to the first embodiment, a first active region 11 (a region indicated by bold lines in FIG. 5) and a second active region 12 (a region indicated by other bold lines in FIG. 5) are formed on a semiconductor substrate S, and an element isolation region 10 is formed between the active regions 11 and 12. A gate electrode 13 is formed in the first active region 11, forming a transistor 14. A gate electrode 15 is formed in the second active region 12 in parallel to the gate electrode 13. High-strain regions 16 are formed in regions which do not overlap with the gate electrode 13 in the active region 11. A high-strain region 17 is formed in a region closer to the transistor 14, and a high-strain region 17′ is formed in a region farther from the transistor 14, of two regions interposing the gate electrode 15 which do not overlap with the gate electrode 15 in the active region 12. The high-strain regions 16, 17, and 17′ are each formed of a material having a lattice constant different from that of Si. A different material means a material having a lattice constant different from that of Si, such as SiGe, SiC, etc.

A strain induced in the channel region 18 of the transistor 14 depends on the size of the high-strain region 17 formed in the active region 12. A larger distance 19 along the channel length direction between the edge closer to the transistor 14, of both the edges of the second active region 12 in the channel length direction, and the opposing edge of the gate electrode 15, and also a larger distance (second geometric parameter) 28 along the channel length direction between the edge farther from the transistor 14, of the second active region 12, and the opposing edge of the gate electrode 15 induce a larger strain in the channel region 18. Here, the channel length direction is defined as a direction parallel to the direction in which a source-to-drain current of the transistor 14 flows, and the channel width direction is defined as a direction perpendicular to the current direction.

The change in the strain in the channel region 18 with respect to the distance 28 decreases as the length (third geometric parameter) 29, along the channel length direction, of the gate electrode 15 disposed on the active region 12 increases. This is because an increase of the distance between the channel region 18 and the high-strain region 17′ reduces the effect of the strain.

Thus, a change in an electrical characteristic of the transistor 14 can be represented by a function of the distance 19, the distance 28, and the gate length 29. Specifically, in order to describe an electrical characteristic change ΔP due to the geometry of an active region near the transistor, let A, B, and C respectively denote, as model parameters, the distance 19, the distance 28, and the gate length 29, then the electrical characteristic change ΔP can be defined by Equation 6-a as follows.

ΔP∝g(A,B,C,W,L) (6-a)

In this embodiment, Equation 6-b or Equation 6-c may be used instead of Equation 6-a:

$$\begin{matrix}Δ P ∝ {g}_{1} ( {A}^{α} ) \times \frac{{g}_{2} ( {B}^{β} )}{{g}_{3} ( {C}^{γ} )} \times {g}_{4} ( W , L ) or & ( 6 \text{-} b ) \\ Δ P ∝ ( {g}_{5} ( {A}^{α} ) + \frac{{g}_{6} ( {B}^{β} )}{{g}_{7} ( {C}^{γ} )} ) \times {g}_{8} ( W , L ) & ( 6 \text{-} c )\end{matrix}$$

where α, β, and γ are fitting parameters modeling the change in an electrical characteristic with respective changes in the geometric parameters A, B, and C; and f(W, L) is a term representing dependence on the channel width W and the gate length L of the transistor.

Although FIG. 5 illustrates the active region disposed near the transistor 14 only on one side along the channel length direction, active regions may be formed on both sides of the transistor 14. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of the both sides achieves a high-accuracy circuit simulation even if the active regions disposed on the both sides of the transistor 14 along the channel length direction have geometries different from each other.

The electrical characteristics affected by the geometry of an active region near the transistor include transistor current, threshold voltage, and leakage current. The technique for reflecting, in circuit design, electrical characteristic changes affected by the geometry of an active region near the transistor is similar to that of the first embodiment.

This embodiment further takes into consideration the parameters B and C, which are also geometric parameters of an active region disposed near the transistor, in addition to that of the first embodiment. Thus, a higher-accuracy circuit simulation can be achieved, thereby allowing semiconductor ICs to be fabricated while avoiding a circuit performance degradation and a reduction in the yield rate.

### Third Embodiment

FIG. 6 illustrates a plan view and a cross-sectional view of a circuit simulated using the circuit simulation method according to the third embodiment of the present disclosure. The cross-sectional view is taken along line B-B′ of the plan view. The same or equivalent structures to those of the second embodiment are designated by the same reference characters.

In FIG. 6, similarly to the second embodiment, a first active region 11 (a region indicated by bold lines in FIG. 6) and a second active region 12 (a region indicated by other bold lines in FIG. 6) are formed on a semiconductor substrate S, and an element isolation region 10 is formed between the active regions 11 and 12. A gate electrode 13 is formed in the first active region 11, forming a transistor 14. A gate electrode 15 is formed in the second active region 12 in parallel to the gate electrode 13. High-strain regions 16 are formed in regions which do not overlap with the gate electrode 13 in the active region 11. A high-strain region 17 is formed in a region closer to the transistor 14, and a high-strain region 17′ is formed in a region farther from the transistor 14, of two regions interposing the gate electrode 15 which do not overlap with the gate electrode 15 in the active region 12. The high-strain regions 16, 17, and 17′ are each formed of a material having a lattice constant different from that of Si. A different material means a material having a lattice constant different from that of Si, such as SiGe, SiC, etc.

A strain induced in the channel region 18 of the transistor 14 depends on the size of the high-strain region 17 formed in the active region 12. A larger distance 19 along the channel length direction between the edge closer to the transistor 14, of both the edges of the second active region 12 in the channel length direction, and the opposing edge of the gate electrode 15, and also a larger distance 28 along the channel length direction between the edge farther from the transistor 14, of the second active region 12, and the opposing edge of the gate electrode 15 induce a larger strain in the channel region 18. Here, the channel length direction is defined as a direction parallel to the direction in which a source-to-drain current of the transistor 14 flows, and the channel width direction is defined as a direction perpendicular to the current direction.

The change in the strain in the channel region 18 with respect to the distance 28 decreases as the gate length 29 of the gate electrode 15 disposed on the active region 12 increases. This is because an increase of the distance between the channel region 18 and the high-strain region 17′ reduces the effect of the strain.

Furthermore, a larger distance (fourth geometric parameter) 30 along the channel length direction between the edge of the active region 11 opposing to the active region 12 across the element isolation region 10 and the opposing edge of the gate electrode 13, and also a larger length (fifth geometric parameter) 31 of the element isolation region 10 along the channel length direction result in a smaller change in the strain in the channel region 18 with respect to the distances 19 and 28. This is because increases of the distances between the channel region 18 and the high-strain regions 17 and 17′ reduce the effects of the strain. However, since the materials of the active region 11 and of the element isolation region 10 are different from each other, that is, Si and oxide, the susceptibility to the change in the magnitude of strain affecting the channel region 18 differs.

Thus, a change in an electrical characteristic of the transistor 14 can be represented by a function of the distance 19, the distance 28, the gate length 29, the distance 30, and the length 31. Specifically, in order to describe an electrical characteristic change ΔP due to the geometry of an active region near the transistor, let A, B, C, D, and E respectively denote, as model parameters, the distance 19, the distance 28, the gate length 29, the distance 30, and the length 31, then the electrical characteristic change ΔP can be defined by Equation 7-a as follows.

ΔP∝h(A,B,C,D,E,W,L) (7-a)

In this embodiment, Equation 7-b or Equation 7-c may be used instead of Equation 7-a:

$$\begin{matrix}Δ P ∝ ( {g}_{1} ( {A}^{α} ) \times \frac{{g}_{2} ( {B}^{β} )}{{g}_{3} ( {C}^{γ} )} ) \times \frac{1}{{g}_{4} ( {D}^{δ} ) {g}_{5} ( {E}^{ɛ} )} \times {g}_{6} ( W , L ) or & ( 7 \text{-} b ) \\ Δ P ∝ ( {g}_{7} ( {A}^{α} ) + \frac{{g}_{8} ( {B}^{β} )}{{g}_{9} ( {C}^{γ} )} ) \times \frac{1}{{g}_{10} ( {D}^{δ} ) {g}_{11} ( {E}^{ɛ} )} \times {g}_{12} ( W , L ) & ( 7 \text{-} c )\end{matrix}$$

where α, β, γ, δ, and ε are fitting parameters modeling the change in an electrical characteristic with respective changes in the geometric parameters A, B, C, D, and E; and f(W, L) is a term representing dependence on the channel width W and the gate length L of the transistor.

Although FIG. 6 illustrates the active region disposed near the transistor 14 only on one side along the channel length direction, active regions may be formed on both sides of the transistor 14. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of the both sides achieves a high-accuracy circuit simulation even if the active regions disposed on the both sides of the transistor 14 along the channel length direction have geometries different from each other.

The electrical characteristics affected by the geometry of an active region near the transistor include transistor current, threshold voltage, and leakage current. The technique for reflecting, in circuit design, electrical characteristic changes affected by the geometry of an active region near the transistor is similar to that of the first embodiment.

This embodiment further takes into consideration the parameters D and E, which are also geometric parameters of an active region disposed near the transistor, in addition to that of the second embodiment. Thus, a still higher-accuracy circuit simulation can be achieved, thereby allowing semiconductor ICs to be fabricated while avoiding a circuit performance degradation and a reduction in the yield rate.

### Fourth Embodiment

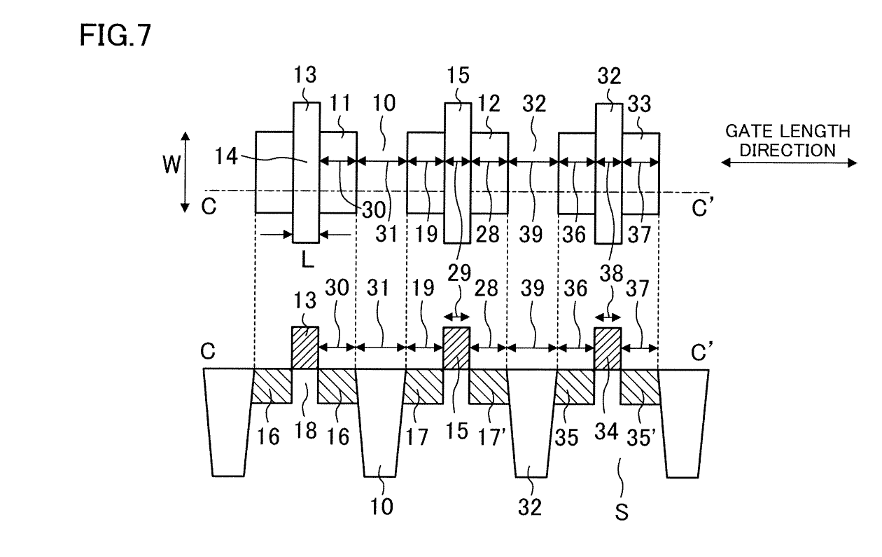

FIG. 7 illustrates a plan view and a cross-sectional view of a circuit simulated using the circuit simulation method according to the fourth embodiment of the present disclosure. The cross-sectional view is taken along line C-C′ of the plan view. The same or equivalent structures to those of the third embodiment are designated by the same reference characters.

In FIG. 7, similarly to the third embodiment, a first active region 11 (a region indicated by bold lines in FIG. 7) and a second active region 12 (a region indicated by other bold lines in FIG. 7) are formed on a semiconductor substrate S, and an element isolation region 10 is formed between the active regions 11 and 12. A gate electrode 13 is formed in the first active region 11, forming a transistor 14. A gate electrode 15 is formed in the second active region 12 in parallel to the gate electrode 13.

In this embodiment, a third active region 33 (a region indicated by still other bold lines in FIG. 7) is formed, on the semiconductor substrate S, on the opposite side from the transistor 14 across an element isolation region 32 in the channel length direction in the active region 12. A gate electrode 34 is formed in the third active region 33 in parallel to the gate electrodes 13 and 15.

High-strain regions 16 are formed in regions which do not overlap with the gate electrode 13 in the active region 11. A high-strain region 17 is formed in a region closer to the transistor 14, and a high-strain region 17′ is formed in a region farther from the transistor 14, of two regions interposing the gate electrode 15 which do not overlap with the gate electrode 15 in the active region 12. In addition, a high-strain region 35 is formed in a region closer to the transistor 14, and a high-strain region 35′ is formed in a region farther from the transistor 14, of two regions interposing the gate electrode 34 which do not overlap with the gate electrode 34 in the active region 33.

The high-strain regions 16, 17, 17′, 35, and 35′ are each formed of a material having a lattice constant different from that of Si. A different material means a material having a lattice constant different from that of Si. such as SiGe, SiC, etc. The material forming the high-strain regions 16, the material forming the high-strain regions 17 and 17′, and the material forming the high-strain regions 35 and 35′ may differ from one another. For example, these high-strain regions may be configured such that the high-strain regions 16, 35, and 35′ have SiGe introduced, and the high-strain regions 17 and 17′ have SiC introduced.

A strain induced in the channel region 18 of the transistor 14 depends on the size of the high-strain region 17 formed in the active region 12. A larger distance 19 along the channel length direction between the edge closer to the transistor 14, of both the edges of the second active region 12 in the channel length direction, and the opposing edge of the gate electrode 15, and also a larger distance 28 along the channel length direction between the edge farther from the transistor 14, of the second active region 12, and the opposing edge of the gate electrode 15 induce a larger strain in the channel region 18. Here, the channel length direction is defined as a direction parallel to the direction in which a source-to-drain current of the transistor 14 flows, and the channel width direction is defined as a direction perpendicular to the current direction.

The change in the strain in the channel region 18 with respect to the distance 28 decreases as the gate length 29 of the gate electrode 15 disposed on the active region 12 increases. This is because an increase of the distance between the channel region 18 and the high-strain region 17′ reduces the effect of the strain.

The strain induced in the channel region 18 of the transistor 14 also depends on the size of the high-strain region 35 formed in the active region 33. A larger distance 36 along the channel length direction between the edge closer to the transistor 14, of both the edges of the active region 33 in the channel length direction, and the opposing edge of the gate electrode 34, and also a larger distance 37 along the channel length direction between the edge farther from the transistor 14, of the active region 33, and the opposing edge of the gate electrode 34 induce a larger strain in the channel region 18.

Furthermore, the change in the strain in the channel region 18 with respect to the distance 37 decreases as the gate length 38 of the gate electrode 34 disposed on the active region 33 increases. This is because an increase of the distance between the channel region 18 and the high-strain region 35′ reduces the effect of the strain.

A larger distance 30 along the channel length direction between the edge of the active region 11 opposing to the active region 12 across the element isolation region 10 and the opposing edge of the gate electrode 13, and also a greater length 31 of the element isolation region 10 along the channel length direction result in a smaller change in the strain in the channel region 18 with respect to the distances 19, 28, 36, and 37. This is because increases of the distances between the channel region 18 and the high-strain regions 17 and 17′ reduce the effects of the strain. However, since the materials of the active region 11 and of the element isolation region 10 are different from each other, that is, Si and oxide, the susceptibility to the change in the magnitude of strain affecting the channel region 18 differs.

In a similar manner, a greater length 39 of the element isolation region 32 along the channel length direction results in a smaller change in the strain in the channel region 18 with respect to the distances 36 and 37.

Thus, a change in an electrical characteristic of the transistor 14 can be represented by a function of the distance 19, the distance 28, the gate length 29, the distance 30, the length 31, the distance 36, the distance 37, the gate length 38, and the length 39. Specifically, in order to describe an electrical characteristic change ΔP due to the geometry of an active region near the transistor, let A, B, C, D, E, F, G, H, and I respectively denote, as model parameters, the distance 19, the distance 28, the gate length 29, the distance 30, the length 31, the distance 36, the distance 37, the gate length 38, and the length (ninth geometric parameter) 39, then the electrical characteristic change ΔP can be defined by Equation 8-a as follows.

ΔP∝i(A,B,C,D,E,F,G,H,I,W,L) (8-a)

In this embodiment, Equation 8-b or Equation 8-c may be used instead of Equation 8-a:

$$\begin{matrix}Δ P ∝ ( {i}_{1} ( {A}^{α} ) \times \frac{{i}_{2} ( {B}^{β} )}{{i}_{3} ( {C}^{γ} )} ) ( ( {i}_{6} ( {F}^{ζ} ) \times \frac{{i}_{7} ( {G}^{η} )}{{i}_{8} ( {H}^{θ} )} ) \times \frac{1}{{i}_{9} ( {I}^{κ} )} ) \times \frac{1}{{i}_{4} ( {D}^{δ} ) {i}_{5} ( {E}^{ɛ} )} \times {i}_{10} ( W , L ) or & ( 8 \text{-} b ) \\ Δ P ∝ ( {i}_{11} ( {A}^{α} ) + \frac{{i}_{12} ( {B}^{β} )}{{i}_{13} ( {C}^{γ} )} ) ( ( {i}_{16} ( {F}^{ζ} ) + \frac{{i}_{17} ( {G}^{η} )}{{i}_{18} ( {H}^{θ} )} ) \times \frac{1}{{i}_{19} ( {I}^{κ} )} ) \times \frac{1}{{i}_{14} ( {D}^{δ} ) {i}_{15} ( {E}^{ɛ} )} \times {i}_{20} ( W , L ) & ( 8 \text{-} c )\end{matrix}$$

where α, β, γ, δ, ε, ζ, η, θ, and κ are fitting parameters modeling the change in an electrical characteristic with respective changes in the geometric parameters A, B, C, D, E, F, G, H, and I; and f(W, L) is a term representing dependence on the channel width W and the gate length L of the transistor.

Although FIG. 7 illustrates the active region disposed near the transistor 14 only on one side along the channel length direction, active regions may be formed on both sides of the transistor 14. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of the both sides achieves a high-accuracy circuit simulation even if the active regions disposed on the both sides of the transistor 14 along the channel length direction have geometries different from each other.

The electrical characteristics affected by the geometry of an active region near the transistor include transistor current, threshold voltage, and leakage current. The technique for reflecting, in circuit design, electrical characteristic changes affected by the geometry of an active region near the transistor is similar to that of the first embodiment.

This embodiment further takes into consideration the parameters F, G, H, and I, which are also geometric parameters of an active region disposed near the transistor, in addition to that of the third embodiment. Thus, a still higher-accuracy circuit simulation can be achieved, thereby allowing semiconductor ICs to be fabricated while avoiding a circuit performance degradation and a reduction in the yield rate.

### Fifth Embodiment

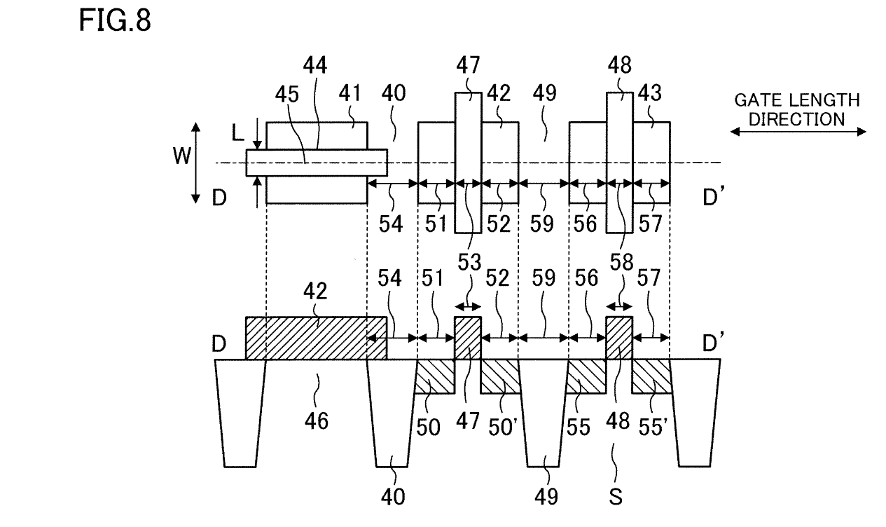

FIG. 8 illustrates a plan view and a cross-sectional view of a simulated using the circuit simulation method according to the fifth embodiment of the present disclosure. The cross-sectional view is taken along line D-D′ of the plan view.

In FIG. 8, a first active region 41 (a region indicated by bold lines in FIG. 8) and a second active region 42 (a region indicated by other bold lines in FIG. 8) are formed on a semiconductor substrate S, and an element isolation region 40 is formed between the active regions 41 and 42. In addition, a third active region 43 (a region indicated by still other bold lines in FIG. 8) is formed, aside of the active region 42, on the opposite side from the active region 41 across the element isolation region 49.

In this embodiment, a gate electrode 44 is formed in the first active region 41, forming a transistor 45, and a channel region 46 is formed underneath the gate electrode 44. A gate electrode 47 and a gate electrode 48 are respectively formed in the second active region 42 and in the third active region 43, each in a perpendicular direction to that of the gate electrode 44.

A high-strain region 50 is formed in a region closer to the transistor 45, and a high-strain region 50′ is formed in a region farther from the transistor 45, of two regions interposing the gate electrode 47 which do not overlap with the gate electrode 47 in the active region 42; and a high-strain region 55 is formed in a region closer to the transistor 45, and a high-strain region 55′ is formed in a region farther from the transistor 45, of two regions interposing the gate electrode 48 which do not overlap with the gate electrode 48 in the active region 43.

The high-strain regions 50, 50′, 55, and 55′ are each formed of a material having a lattice constant different from that of Si. A different material means a material having a lattice constant different from that of Si, such as SiGe, SiC, etc. The material forming the high-strain regions 50 and 50′ and the material forming the high-strain regions 55 and 55′ may differ from each other. For example, these high-strain regions may be configured such that the high-strain regions 50 and 50′ have SiGe introduced, and the high-strain regions 55 and 55′ have SiC introduced.

A strain induced in the channel region 46 of the transistor 45 depends on the size of the high-strain region 50 formed in the active region 42. A larger distance (first geometric parameter) 51 along the channel width direction between the edge closer to the transistor 45, of both the edges of the active region 42 in the channel width direction, and the opposing edge of the gate electrode 47, and also a larger distance (second geometric parameter) 52 along the channel width direction between the edge farther from the transistor 45, of the active region 42, and the opposing edge of the gate electrode 47 induce a larger strain in the channel region 46. Here, the channel width direction is defined as a direction perpendicular to the direction in which a source-to-drain current of the transistor 45 flows, and the channel length direction is defined as a direction parallel to the current direction.

Furthermore, the change in the strain in the channel region 46 with respect to the distance 52 decreases as the width (third geometric parameter) 53, along the channel width direction, of the gate electrode 47 disposed on the active region 42 increases. This is because an increase of the distance between the channel region 46 and the high-strain region 50′ reduces the effect of the strain.

The strain induced in the channel region 46 of the transistor 45 also depends on the size of the high-strain region 55 formed in the active region 43. A larger distance (fifth geometric parameter) 56 along the channel width direction between the edge closer to the transistor 45, of both the edges of the active region 43 in the channel width direction, and the opposing edge of the gate electrode 48, and also a larger distance (sixth geometric parameter) 57 along the channel width direction between the edge farther from the transistor 45, of the active region 43, and the opposing edge of the gate electrode 48 induce a larger strain in the channel region 46.

Furthermore, the change in the strain in the channel region 46 with respect to the distance 57 decreases as the gate length (seventh geometric parameter) 58 of the gate electrode 48 disposed on the active region 43 increases. This is because an increase of the distance between the channel region 46 and the high-strain region 55′ reduces the effect of the strain.

In addition, a larger width (fourth geometric parameter) 54 of the element isolation region 40 along the channel width direction results in a smaller change in the strain of the channel region 46 with respect to the distance 51, the distance 52, the distance (fifth geometric parameter) 56, and the distance (sixth geometric parameter) 57. This is because increases of the distances between the channel region 46 and the high-strain regions 50, 50′, 55, and 55′ reduce the effects of the strain.

Similarly, a larger width (eighth geometric parameter) 59 of the element isolation region 49 along the channel width direction results in a smaller change in the strain in the channel region 46 with respect to the distances 56 and 57.

Thus, a change in an electrical characteristic of the transistor 45 can be represented by a function of the distance 51, the distance 52, the width 53, the width 54, the distance 56, the distance 57, the width 58, and the width 59. Specifically, in order to describe an electrical characteristic change ΔP due to the geometry of an active region near the transistor, let A, B, C, D, E, F, G, and H respectively denote, as model parameters, the distance 51, the distance 52, the width 53, the width 54, the distance 56, the distance 57, the gate length (seventh geometric parameter) 58 of the gate electrode 48, and the width (eighth geometric parameter) 59 of the element isolation region 49, then the electrical characteristic change ΔP can be defined by Equation 9-a as follows.

ΔP∝j(A,B,C,D,E,F,G,H,W,L) (9-a)

In this embodiment, Equation 9-b or Equation 9-c may be used instead of Equation 9-a:

$$\begin{matrix}Δ P ∝ ( {j}_{1} ( {A}^{α} ) \times \frac{{j}_{2} ( {B}^{β} )}{{j}_{3} ( {C}^{γ} )} ) ( ( {j}_{5} ( {E}^{ɛ} ) \times \frac{{j}_{6} ( {F}^{ζ} )}{{j}_{7} ( {G}^{η} )} ) \times \frac{1}{{j}_{8} ( {H}^{θ} )} ) \times \frac{1}{{j}_{4} ( {D}^{δ} )} \times {j}_{9} ( W , L ) or & ( 9 \text{-} b ) \\ Δ P ∝ ( {j}_{10} ( {A}^{α} ) + \frac{{j}_{11} ( {B}^{β} )}{{j}_{12} ( {C}^{γ} )} ) ( ( {j}_{14} ( {E}^{ɛ} ) + \frac{{j}_{15} ( {F}^{ζ} )}{{j}_{16} ( {G}^{η} )} ) \times \frac{1}{{j}_{17} ( {H}^{θ} )} ) \times \frac{1}{{j}_{13} ( {D}^{δ} )} \times {j}_{18} ( W , L ) & ( 9 \text{-} c )\end{matrix}$$

where α, β, γ, δ, ε, ζ, and θ are fitting parameters modeling the change in an electrical characteristic with respective changes in the geometric parameters A, B, C, D, E, F, G, and H; and f(W, L) is a term representing dependence on the channel width W and the gate length L of the transistor.

Although FIG. 8 illustrates the active region disposed near the transistor 45 only on one side along the channel width direction, active regions may be formed on both sides of the transistor 45. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of the both sides achieves a high-accuracy circuit simulation even if the active regions disposed on the both sides of the transistor 45 along the channel width direction have geometries different from each other.

The electrical characteristics affected by the geometry of an active region near the transistor include transistor current, threshold voltage, and leakage current. The technique for reflecting, in circuit design, electrical characteristic changes affected by the geometry of an active region near the transistor is similar to that of the first embodiment.

By using the circuit simulation method according to this embodiment, changes in electrical characteristics due to the layout pattern of an active region disposed along the channel width direction near the transistor can be estimated with high accuracy during the design stage, thereby allowing semiconductor ICs to be fabricated while avoiding a circuit performance degradation and a reduction in the yield rate.

Although this embodiment calculates electrical characteristics of the transistor based on the first through eighth geometric parameters, it is evident that electrical characteristics of the transistor may be calculated based only on the first geometric parameter as with the first embodiment, only on the first through third geometric parameters as with the second embodiment, or only on the first through fifth geometric parameters as with the third embodiment.

### Sixth Embodiment

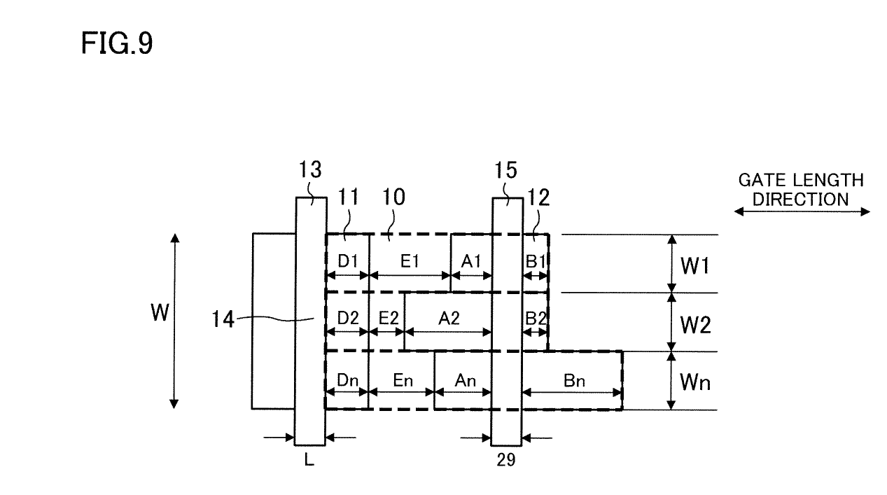

FIG. 9 illustrates a plan view of a circuit simulated using the circuit simulation method according to the sixth embodiment of the present disclosure. The same or equivalent structures to those of the third embodiment are designated by the same reference characters. The modeling technique of this embodiment differs from that of the third embodiment in that, as shown in FIG. 9, even an irregular geometry of the active region 12 near the transistor 14 can be modeled.

In FIG. 9, similarly to the third embodiment, a first active region 11 and a second active region 12 are formed on a semiconductor substrate S, and an element isolation region 10 is formed between the active regions 11 and 12. A first gate electrode 13 is formed in the first active region 11, forming a transistor 14. A second gate electrode 15 is formed in the second active region 12 in parallel to the gate electrode 13. High-strain regions, each formed of a material having a lattice constant different from that of Si, are formed in regions which do not overlap with the gate electrode 13 in the active region 11 and in regions which do not overlap with the gate electrode 15 in the active region 12. A different material means a material having a lattice constant different from that of Si, such as SiGe, SiC, etc.

The region between the edge, opposite the second active region 12, of the gate electrode 13 in the first active region 11 and the edge farther from the transistor 14 of both the edges of the second active region 12 in the channel length direction is divided into n (where n is an integer greater than or equal to two) rectangular regions (regions enclosed by broken lines in FIG. 9). The rectangular regions are created so as not to include the corners of the first and second active regions 11 and 12. The sum of the lengths Wi (where i represents any integer from one to n) of the respective rectangular regions along the channel width direction is equal to the channel width of the transistor 14. Here, the channel length direction is defined as a direction parallel to the direction in which a source-to-drain current of the transistor 14 flows, and the channel width direction is defined as a direction perpendicular to the current direction.

For each of the rectangular regions, let Ai denote the distance (tenth geometric parameter) between the edge closer to the transistor 14 of both the edges of the second active region 12 in the channel length direction and the opposing edge of the second gate electrode 15; let Bi denote the distance (eleventh geometric parameter) between the edge farther from the transistor 14 of both the edges of the second active region 12 in the channel length direction and the opposing edge of the second gate electrode 15; let Di denote the distance (thirteenth geometric parameter) between the edge, opposite the second active region 12, of the first gate electrode 13 and the edge of the first active region 11; and let Ei denote the width (fourteenth geometric parameter) of the element isolation region 10 between the first and the second active regions 11 and 12.

A strain induced in the channel region of the transistor 14 depends on the magnitudes of the distances Ai and Bi of the active region 12 in each rectangular region. The change in strain induced in the channel region with respect to the distance Bi decreases as the gate length 29 of the gate electrode 15 disposed on the active region 12 increases. This is because an increase of the distance from the channel region reduces the effect of the strain. Similarly, the change in the strain induced in the channel region with respect to the distances Ai and Bi decreases as the distance Di of the first active region 11 and the width Ei of the element isolation region 10 in each rectangular region increase.

Thus, in order to describe an electrical characteristic change ΔP due to the geometry of an active region near the transistor, let C denote, as a mode parameter, the gate width (twelfth geometric parameter) 29 of the gate electrode 15 in the second active region 12, then the electrical characteristic change ΔP can be defined by Equation 10-a as follows.

$$Δ P ∝ \frac{Wi}{W} {\sum }_{i = 1}^{n} k ( Ai , Bi , C , Di , Ei , W , L ) \qquad ( 10 \text{-} a )$$

In this embodiment, Equation 10-b or Equation 10-c may be used instead of Equation 10-a:

$$\begin{matrix}Δ P ∝ \frac{Wi}{W} {\sum }_{i = 1}^{n} [ ( {k}_{1} ( {Ai}^{α} ) \times \frac{{k}_{2} ( {Bi}^{β} )}{{k}_{3} ( {C}^{γ} )} ) \times \frac{1}{{k}_{4} ( {Di}^{δ} ) {k}_{5} ( {Ei}^{ɛ} )} ] \times {k}_{6} ( W , L ) \\ or & ( 10 \text{-} b ) \\ Δ P ∝ \frac{Wi}{W} {\sum }_{i = 1}^{n} [ ( {k}_{1} ( {Ai}^{α} ) + \frac{{k}_{2} ( {Bi}^{β} )}{{k}_{3} ( {C}^{γ} )} ) \times \frac{1}{{k}_{4} ( {Di}^{δ} ) {k}_{5} ( {Ei}^{ɛ} )} ] \times {k}_{6} ( W , L ) & ( 10 \text{-} c )\end{matrix}$$

where α, β, γ, δ, and ε are fitting parameters modeling the change in an electrical characteristic with respective changes in the geometric parameters Ai, Bi, C, Di, and Ei; and f(W, L) is a term representing dependence on the channel width W and the gate length L of the transistor.

Although FIG. 9 illustrates the active region disposed near the transistor 14 only on one side along the channel length direction, active regions may be formed on both sides of the transistor 14. If that is the case, effects of the both sides need to be taken into consideration. One technique of reflecting the effects of the both sides is to let ΔPr denote the change in an electrical characteristic due to the layout on one side, and to let ΔPl denote the change in the electrical characteristic on the other side, and then to assume that the overall change ΔP in the electrical characteristic has a relationship ΔP=ΔPr+ΔPl. Another technique of reflecting the effects of the both sides is to use a relationship 1/ΔP=1/ΔPr+1/ΔPl. Reflecting the effects of the both sides achieves a high-accuracy circuit simulation even if the active regions disposed on the both sides of the transistor 14 along the channel length direction have geometries different from each other.

The electrical characteristics affected by the geometry of an active region near the transistor include transistor current, threshold voltage, and leakage current. The technique for reflecting, in circuit design, electrical characteristic changes affected by the geometry of an active region near the transistor is similar to that of the first embodiment.

This embodiment divides each of the active regions near the transistor into rectangular regions, determines weights based respectively on the lengths of the rectangular regions along the channel width direction, and computes the averages. Thus, a still higher-accuracy circuit simulation can be achieved than that of the third embodiment even if the geometry of an active region near the transistor is irregular, thereby allowing semiconductor ICs to be fabricated while avoiding a circuit performance degradation and a reduction in the yield rate.

As described above, the present invention provides a modeling method for representing dependence on the geometry of an active region near the transistor, and is thus useful for a circuit simulation method which can improve the accuracy in designing a semiconductor IC having a small feature size.

What is claimed is:

1. A circuit simulation method for calculating, using a computer and a memory, an electrical characteristic of a transistor formed on a semiconductor substrate and having an active region and a gate electrode surrounded by an element isolation region, in a circuit including the transistor, the circuit also including both an adjacent active region disposed across the element isolation region in a gate length direction of the transistor, and an adjacent gate electrode disposed on the adjacent active region in parallel to the gate electrode of the transistor, where a region not overlapping with the adjacent gate electrode in the adjacent active region is formed of a material having a lattice constant different from that of the semiconductor substrate, comprising:
storing by the computer, in the memory, a gate length and a channel width of the transistor, and a distance between an edge closer to the transistor, of both edges of the adjacent active region, and the adjacent gate electrode as a first geometric parameter, and
calculating by the computer the electrical characteristic of the transistor based on the gate length and the channel width of the transistor and on the first geometric parameter stored in the memory.

2. The circuit simulation method of claim 1, wherein
the storing by the computer further includes storing, in the memory, a distance between an edge farther from the transistor, of both the edges of the adjacent active region, and the adjacent gate electrode as a second geometric parameter, and storing, in the memory, a gate length of the adjacent gate electrode as a third geometric parameter, and
the calculating by the computer the electrical characteristic of the transistor based on the gate length and the channel width of the transistor and on the first through third geometric parameters stored in the memory.

3. The circuit simulation method of claim 2, wherein
the storing by the computer further includes storing, in the memory, a distance between an edge closer to the adjacent active region, of both edges of the active region of the transistor, and the gate electrode of the transistor as a fourth geometric parameter, and storing, in the memory, a length of the element isolation region between the active region of the transistor and the adjacent active region along the gate length direction of the transistor as a fifth geometric parameter, and
the calculating by the computer the electrical characteristic of the transistor based on the gate length and the channel width of the transistor and on the first through fifth geometric parameters stored in the memory.

4. The circuit simulation method of claim 3, wherein
the circuit further includes an opposite adjacent active region disposed on an opposite side from the transistor in the adjacent active region across an element isolation region in the gate length direction of the transistor, and includes an opposite adjacent gate electrode disposed on the opposite adjacent active region in parallel to the gate electrodes of the transistors, and
if a region not overlapping with the opposite adjacent gate electrode in the opposite adjacent active region is formed of a material having a lattice constant different from that of the semiconductor substrate,
the storing by the computer further includes storing, in the memory, a distance between an edge closer to the transistor, of both edges of the opposite adjacent active region, and the opposite adjacent gate electrode as a sixth geometric parameter, a distance between an edge farther from the transistor, of both the edges of the opposite adjacent active region, and the opposite adjacent gate electrode as a seventh geometric parameter, a gate length of the opposite adjacent gate electrode as an eighth geometric parameter, and a length of the element isolation region between the adjacent active region and the opposite adjacent active region along the channel length direction as a ninth geometric parameter, and
the calculating by the computer the electrical characteristic of the transistor based on the gate length and the channel width of the transistor and on the first through ninth geometric parameters stored in the memory.

5. The circuit simulation method of claim 3, wherein
if a region, in the circuit, between the edge closer to the gate electrode of the transistor, of both the edges of the active region of the transistor and the edge farther from the transistor of both the edges of the adjacent active region is divided into n (where n is an integer greater than or equal to two) rectangular regions along a gate width direction of the transistor, and a sum of lengths of the n rectangular regions along the gate width direction of the transistor is equal to the length of the transistor along the gate width direction,
the storing by the computer, in the memory, a distance between the edge closer to the transistor of both the edges of the adjacent active region and the adjacent gate electrode as a tenth geometric parameter, a distance between the edge farther from the transistor of both the edges of the adjacent active region and the adjacent gate electrode as an eleventh geometric parameter, a gate width of the adjacent gate electrode as a twelfth geometric parameter, a distance between the edge closer to the adjacent active region of both the edges of the active region of the transistor and the gate electrode of the transistor as a thirteenth geometric parameter, and a length of the element isolation region between the active region of the transistor and the adjacent active region along the gate length direction as a fourteenth geometric parameter, and
the calculating by the computer the electrical characteristic of the transistor based on the gate length and the channel width of the transistor and on the tenth through fourteenth geometric parameters of each of the n rectangular regions, instead of the first through fifth geometric parameters, stored in the memory.

6. A circuit simulation method for calculating, using a computer and a memory, an electrical characteristic of a transistor formed on a semiconductor substrate and having an active region and a gate electrode surrounded by an element isolation region, in a circuit including the transistor, the circuit also including both an adjacent active region disposed across the element isolation region in a gate width direction of the transistor, and an adjacent gate electrode disposed on the adjacent active region perpendicular to the gate electrode of the transistor, where a region not overlapping with the adjacent gate electrode in the adjacent active region is formed of a material having a lattice constant different from that of the semiconductor substrate, comprising:
storing by the computer, in the memory, a gate length and a channel width of the transistor, and a distance between an edge closer to the transistor, of both edges of the adjacent active region, and the adjacent gate electrode as a first geometric parameter, and
calculating by the computer the electrical characteristic of the transistor based on the gate length and the channel width of the transistor and on the first geometric parameter stored in the memory.

7. The circuit simulation method of claim 6, wherein
the storing by the computer further includes storing, in the memory, a distance between an edge farther from the transistor, of both the edges of the adjacent active region, and the adjacent gate electrode as a second geometric parameter, and storing, in the memory, a gate length of the adjacent gate electrode as a third geometric parameter, and
the calculating by the computer the electrical characteristic of the transistor based on the gate length and the channel width of the transistor and on the first through third geometric parameters stored in the memory.

8. The circuit simulation method of claim 7, wherein
the storing by the computer further includes storing, in the memory, a length of the element isolation region between the active region of the transistor and the adjacent active region along the gate width direction of the transistor as a fourth geometric parameter, and
the calculating by the computer the electrical characteristic of the transistor based on the gate length and the channel width of the transistor and on the first through fourth geometric parameters stored in the memory.

9. The circuit simulation method of claim 8, wherein
the circuit further includes an opposite adjacent active region disposed on an opposite side from the transistor in the adjacent active region across the element isolation region in the gate width direction of the transistor, and includes an opposite adjacent gate electrode disposed on the opposite adjacent active region in parallel to the adjacent gate electrode, and
if a region not overlapping with the opposite adjacent gate electrode in the opposite adjacent active region is formed of a material having a lattice constant different from that of the semiconductor substrate,
the storing by the computer further includes storing, in the memory, a distance between an edge closer to the transistor, of both edges of the opposite adjacent active region, and the opposite adjacent gate electrode as a fifth geometric parameter, a distance between an edge farther from the transistor, of both the edges of the opposite adjacent active region, and the opposite adjacent gate electrode as a sixth geometric parameter, and a gate length of the opposite adjacent gate electrode as a seventh geometric parameter, and
the calculating by the computer the electrical characteristic of the transistor based on the gate length and the channel width of the transistor and on the first through seventh geometric parameters stored in the memory.

10. The circuit simulation method of claim 1, wherein
the storing by the computer includes extracting the geometric parameter from mask layout data.

11. The circuit simulation method of claim 1, wherein
the electrical characteristic of the transistor calculated is a current flowing through the transistor, a threshold voltage of the transistor, or a leakage current.

12. The circuit simulation method of claim 1, wherein
the circuit simulation method calculates, using the computer and the memory, the electrical characteristic of the transistor in the circuit in which the material having a lattice constant different from that of the semiconductor substrate is SiGe.

13. The circuit simulation method of claim 1, wherein
the circuit simulation method calculates, using the computer and the memory, the electrical characteristic of the transistor in the circuit in which the material having a lattice constant different from that of the semiconductor substrate is SiC.

14. A semiconductor integrated circuit designed using the circuit simulation method of claim 1.

15. The circuit simulation method of claim 6, wherein
the storing by the computer includes extracting the geometric parameter from mask layout data.

16. The circuit simulation method of claim 6, wherein
the electrical characteristic of the transistor calculated is a current flowing through the transistor, a threshold voltage of the transistor, or a leakage current.

17. The circuit simulation method of claim 6, wherein
the circuit simulation method calculates, using the computer and the memory, the electrical characteristic of the transistor in the circuit in which the material having a lattice constant different from that of the semiconductor substrate is SiGe.

18. The circuit simulation method of claim 6, wherein
the circuit simulation method calculates, using the computer and the memory, the electrical characteristic of the transistor in the circuit in which the material having a lattice constant different from that of the semiconductor substrate is SiC.

19. A semiconductor integrated circuit designed using the circuit simulation method of claim 6.
